(19) United States
(12) Patent Application Publication
(10) Pub. No.: US 2024/0357744 A1
(43) Pub. Date: Oct. 24, 2024

(54) INTEGRATED CIRCUIT PACKAGES INCLUDING CARRIERS WITH INCORPORATED SUBSTRATES AND INTERFACES

(71) Applicant: Intel Corporation, Santa Clara, CA (US)

(72) Inventors: Rick Canham, West Richland, WA (US); Jeffory L. Smalley, Olympia, WA (US); Steven Adam Klein, Chandler, AZ (US); Shelby Ann Ferguson, El Dorado Hills, CA (US)

(73) Assignee: Intel Corporation, Santa Clara, CA (US)

(21) Appl. No.: 18/756,949

(22) Filed: Jun. 27, 2024

(51) Int. Cl. H05K 1/11; H05K 1/02; H05K 5/00

(52) U.S. Cl. CPC H05K 1/117; H05K 1/0203; H05K 1/111; H05K 5/0034; H05K 2201/10189

(57) ABSTRACT

Integrated circuit packages including carriers with incorporated substrates and interfaces are disclosed herein. An integrated circuit package carrier disclosed herein includes a frame including an opening to receive an integrated circuit package and at least one of (1) a circuitry component on a substrate on a surface of the frame or (2) a cable interface directly coupled to the frame.

### BACKGROUND

Some integrated circuit packages include carriers that facilitate the coupling of a heat sink to the package and the coupling of the integrated circuit package to a printed circuit board. Some carriers include markers and/or other features to assist with the alignment of the integrated circuit package on the printed circuit board.

### BRIEF DESCRIPTION OF THE DRAWINGS

FIG. 1 is an exploded view of an example compute unit assembly including an integrated circuit package and an example first carrier implemented in accordance with teachings of this disclosure.

FIG. 2A is a perspective view of the example carrier and integrated circuit package of FIG. 1.

FIG. 2B is a top view of the example carrier and integrated circuit package of FIG. 1.

FIG. 2C is a bottom view of the example carrier and integrated circuit package of FIG. 1.

FIG. 3A is a perspective detail view of the example carrier and integrated circuit package of FIGS. 1-2C.

FIG. 3B is a top view of a tab of the example carrier of FIGS. 1-2C.

FIG. 4 is a perspective view of another example carrier and integrated circuit package assembly implemented in accordance with teachings of this disclosure.

In general, the same reference numbers will be used throughout the drawing(s) and accompanying written description to refer to the same or like parts. The figures are not necessarily to scale.

### DETAILED DESCRIPTION

Integrated circuit packages are often coupled to a printed circuit board via a surface mounting system, such as a land grid array (LGA). LGAs are formed between a plurality of pins in a socket of the printed circuit board and a plurality of lands on the integrated circuit package. To facilitate an electrical connection between the pins of the printed circuit board and the lands of the integrated circuit package, some known integrated circuit packages are held in compression against the printed circuit board. In recent years, as the processing capabilities of integrated circuit packages have increased, the density of lands on the underside of the integrated circuit package has increased the difficulty of the routing of traces through the printed circuit board to the integrated circuit package and the packaging of components on the printed circuit board near the integrated circuit package. Another problem associated with known printed circuit board assemblies is the routing of fiber optics to the integrated circuit packages due to the relatively large minimum bending radius of fiber optics cables.

Furthermore, as the processing density of integrated circuit packages increases, the density of connections between integrated circuit packages and sockets accordingly increases. The increased density of connections correspondingly increases the required compressive load to mount the integrated circuit package. The high loads required to support the connections of the LGA can cause a warpage of the integrated circuit package and/or printed circuit board, which can reduce the efficiency of pin-land connections near the center of the integrated circuit board. Additionally, the increased density of connections between the integrated circuit packages and sockets can cause prior assemblies to have severely constrained packaging space to route traces through the printed circuit board to each of the connections.

Examples disclosed herein mitigate some or all of the above-noted deficiencies and include integrated circuit package carriers (referred to herein as “carriers”) with incorporated substrates (e.g., semiconductor substrates, a base substrate, etc.), cable interfaces, and other circuit components. Some example carriers disclosed herein include frames with incorporated substrates and circuitry components. Some such example carriers disclosed herein include frames with a wireless communication die and/or an antenna disposed thereon. Some example carriers disclosed herein include carriers with substrates that include silicon dies and/or passive circuit components disposed thereon. Some such example carriers disclosed herein include traces and/or ribbon cables that extend between the components mounted on the substrate disposed on the carrier and a top and/or side surface of the integrated circuit package. Some example carriers disclosed herein include cable interfaces that are integrally formed with the frame of the carrier. Some example carriers disclosed herein enable the routing of connections into the top and/or side of an integrated circuit package, which can facilitate the coupling of fiber optic cables to an integrated circuit package. Some examples disclosed herein include carriers with heat-producing components with a direct thermal interface with the heat sink coupled to the integrated circuit package associated with the carrier. Examples disclosed herein increase the available packaging and routing space available to integrated circuit packages. Examples disclosed herein do not increase the density of LGA connections and the force required to mount the integrated circuit package on the printed circuit board.

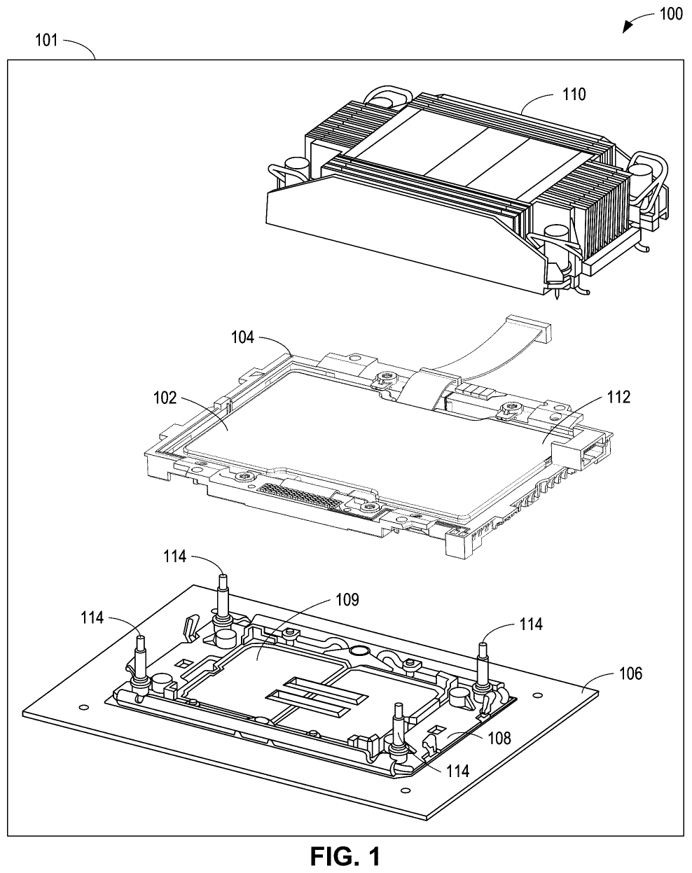

FIG. 1 is an exploded view of a compute unit assembly 100 disposed in an example electronic device 101. In the illustrated example of FIG. 1, the compute unit assembly 100 includes an example integrated circuit package 102 and an example carrier 104 implemented in accordance with teachings of this disclosure. In the illustrated example of FIG. 1, the compute unit assembly 100 includes an example printed circuit board 106, an example bolster plate 108, an example socket 109, and an example heat sink 110.

The electronic device 101 houses and is operated by the compute unit assembly 100. In some examples, the electronic device 101 can be implemented by any suitable electronic device, including a mobile device (e.g., a cell phone, a smartphone, a tablet, a laptop, a smartwatch, etc.), a server, a personal computer, a workstation, a self-learning machine (e.g., a neural network), a personal digital assistant (PDA), an Internet appliance, a headset (e.g., an augmented reality (AR) headset, a virtual reality (VR) headset, etc.) or another wearable device, or any other type of computing and/or electronic device. In some examples, the electronic device 101 can include multiple additional compute unit assemblies similar to the compute unit assembly 100.

The integrated circuit package 102 includes one or more dies and related electric components coupled to a package substrate. For example, the integrated circuit package 102 can include one or more semiconductor die(s), which are also referred to herein as “chips,” and/or “chiplets.” In the illustrated example of FIG. 1, the processor components of the integrated circuit package (e.g., the silicon dies, etc.) are enclosed by an example package lid 112, which is also referred to herein as a “cap” or a “mold.” The package lid 112 houses and/or protects the components of the integrated circuit package 102. In some examples, the package lid 112 is composed of a thermally conductive material (e.g., copper, aluminum, etc.), which thermally conducts and spreads heat from the heat-producing components of the integrated circuit package 102 (e.g., the semiconductor dies, etc.). In some such examples, the package lid 112 forms a thermal interface with the heat sink 110.

The integrated circuit package 102 can be electrically coupled to the socket 109 of the printed circuit board 106 via a land grid array (LGA) connection formed between a plurality of pins and a corresponding plurality of lands. In other examples, the integrated circuit package 102 can be coupled to the printed circuit board 106 via another type of surface mounting (e.g., a ball grid array (BGA) connection, etc.). The integrated circuit package 102 can be implemented by a system-on-chip (SOC) package, a central processing unit, a graphic processing unit, a digital signal processor, an accelerator, etc.

The printed circuit board 106 is the platform that mounts and supports the integrated circuit package 102 and other components associated with the compute unit assembly 100 (e.g., memory, input/output devices, etc.). In some examples, the printed circuit board 106 includes multiple metal layers separated from one another by layers of dielectric material and interconnected by electrically conductive vias. In the illustrated example, the printed circuit board 106 includes the socket 109. The socket 109 receives the integrated circuit package 102 and electrically couples the integrated circuit package 102 to other components mounted on and/or coupled to the printed circuit board 100 via the traces in the printed circuit board 106. The bolster plate 108 is coupled to the printed circuit board 106 around the socket 109. The bolster plate 108 is a stiffener, which mitigates (e.g., prevents, reduces, etc.) the bending of the printed circuit board 106. associated with the assembly of the compute unit assembly 100. In some examples, the bolster plate 108 is absent.

The heat sink 110 is thermally coupled to the integrated circuit package 102 and receives heat therefrom. For example, the heat sink 110 can be mechanically coupled to the integrated circuit package 102 in compression such that the body of the heat sink 110 abuts a heat spreader of the integrated circuit package 102 (e.g., a heat spreader similar to the package lid 112, etc.). In some examples, the interface between the heat sink 110 between the integrated circuit package 102 can be facilitated by a thermally conductive paste. In the illustrated example of FIG. 1, the heat sink 110 includes a plurality of fins, which dissipate heat into the ambient environment of the compute unit assembly 100. In some examples, the compute unit assembly can be disposed in an environment that includes a fluid flow (e.g., an airflow, an immersion coolant flow, etc.), which increases the rate of heat transfer between the heat sink 110 and the ambient environment. In some examples, the heat sink 110 does not include fins and/or can be a cold plate and/or another suitable type of heat sink.

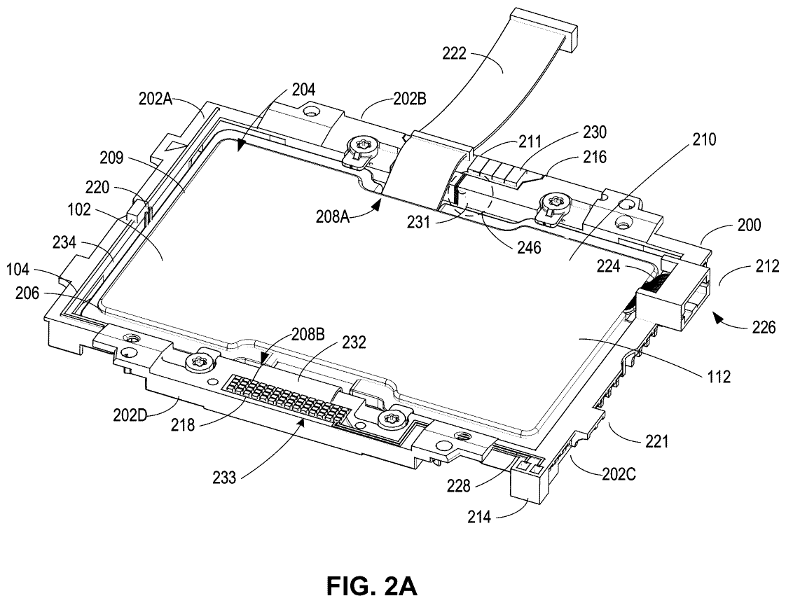

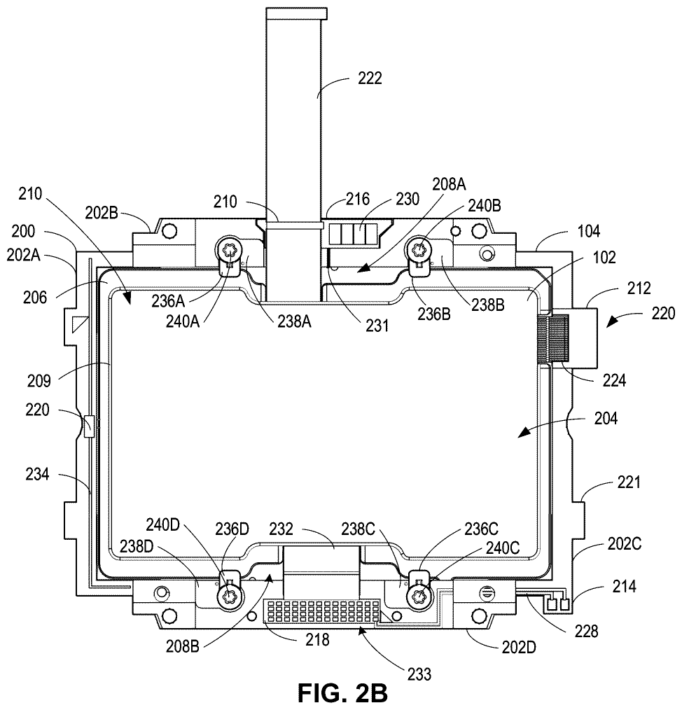

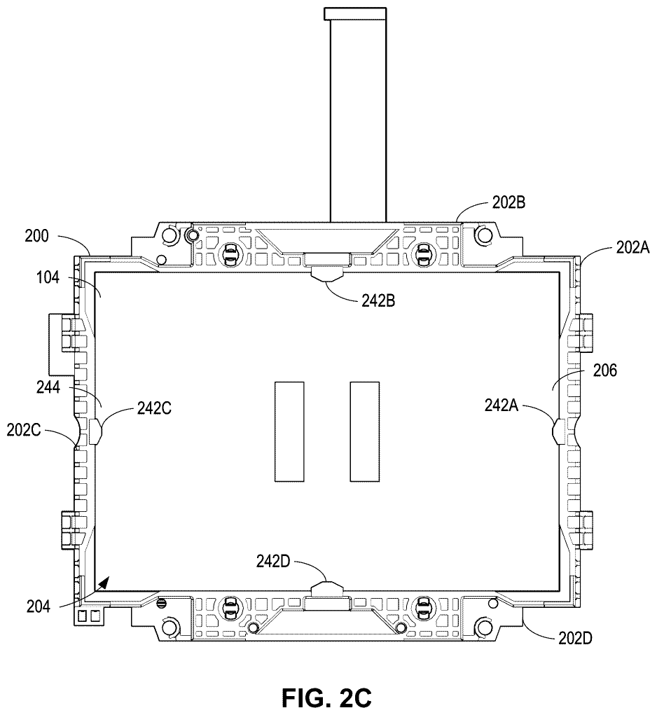

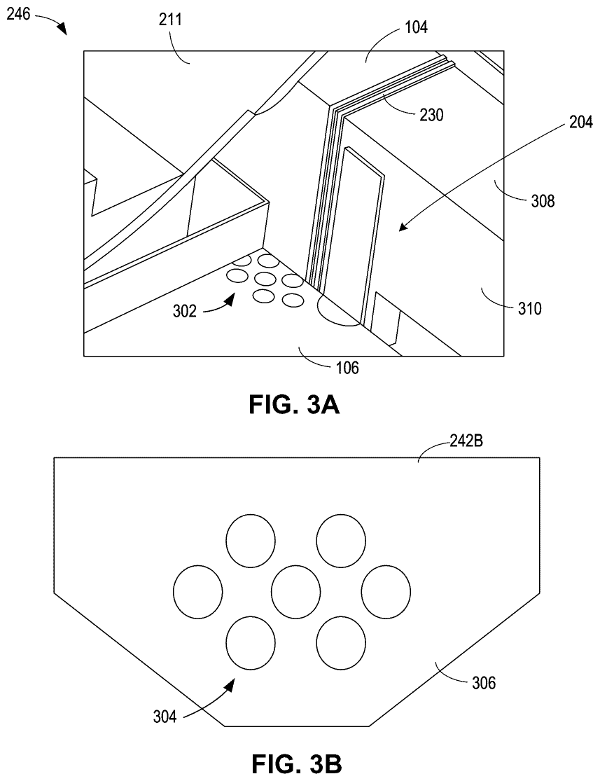

The carrier 104 is an integrated circuit package carrier, which is also referred to herein as a “carrier clip.” In the illustrated example of FIG. 1, the carrier 104 supports the integrated circuit package 102 and facilitates the coupling of the integrated circuit package 102 to the bolster plate 108 and the heat sink 110. The carrier 104 supports and facilitates the alignment of the integrated circuit package 102 and the bolster plate 108. In some examples, the carrier 104 enables the integrated circuit package 102 to be removed from the bolster plate 108 without decoupling the heat sink 110 from the integrated circuit package 102. In the illustrated example of FIG. 1, the carrier 104 includes a plurality of cable interfaces, dies, and other features that are mounted thereon. In some examples, the features mounted to the carrier 104 increase the processing density of the integrated circuit package 102 without increasing the connection density between the integrated circuit package 102 and the socket 109. The carrier 104 and the example features disposed thereon are described in additional detail below in conjunction with FIG. 2A-3B.

When the compute unit assembly 100 is assembled, the heat sink 110 is coupled to the bolster plate 108 and/or printed circuit board 106. For example, the heat sink 110 can be coupled to the plurality of fasteners 114, which retains the integrated circuit package 102 on the printed circuit board 106 and facilitates the electrical connection formed between the integrated circuit package 102 and the socket 109. In the illustrated example of FIG. 1, the carrier 104 includes interfaces, which enable the routing of connections between the integrated circuit package 102 and other components to be coupled to a top surface and/or a side surface of the integrated circuit package 102. In some such examples, the routing of such connections through the carrier 104 reduces the density of connections associated with the mounting of the integrated circuit package 102 on the socket 109 and the associated required compressive load exerted by the fasteners 114. In the illustrated example of FIG. 1, the fasteners 114 extend through the heat sink 110, the integrated circuit package 102, and the bolster plate 108. In the illustrated example of FIG. 1, the carrier 104 is not a load-bearing component (e.g., the compressive load exerted by the fasteners 114 is not transferred through the carrier 104, etc.). In other examples, the carrier 104 can include features (e.g., threaded holes, etc.) that enable the carrier 104 to carry the load associated with the tightening of the fasteners 114.

FIG. 2A is a perspective view of the carrier 104 and the integrated circuit package 102 of FIG. 1. FIG. 2B is a top view of the carrier 104 and integrated circuit package 102 of FIG. 2. In the illustrated example of FIGS. 2A and 2B, the carrier 104 includes an example frame 200 having an example first side 202A, an example second side 202B, an example third side 202C, and an example fourth side 202D. In the illustrated example of FIGS. 2A and 2B, the integrated circuit package 102 defines an example opening 204. In the illustrated example of FIGS. 2A and 2B, the carrier 104 includes the example package lid 112 of FIG. 1 and an example package substrate 206. In the illustrated example of FIGS. 2A and 2B, the package lid 112 includes an example first recessed portion 208A and an example second recessed portion 208B. In the illustrated example of FIGS. 2A and 2B, the package substrate 206 includes an example edge 209 and an example top surface 210. In the illustrated example of FIGS. 2A and 2B, the frame 200 of the carrier 104 includes an example first cable interface 211, an example second cable interface 212, an example component interface 214, an example first substrate 216, an example second substrate 218, and an example die 220. In the illustrated example of FIGS. 2A and 2B, the carrier 104 includes an example alignment feature 221.

In the illustrated example of FIGS. 2A and 2B, the carrier 104 is received by the opening 204 of the frame 200. In the illustrated example of FIGS. 2A and 2B, the frame 200 is an integral component that supports the integrated circuit package 102, the cable interfaces 211, 212, the component interface 214, the substrates 216, 218, and the die 220. In some such examples, the frame 200 can be manufactured via molding (e.g., injection molding, etc.) and/or additive manufacturing. In other examples, the frame 200 can be composed of one or more discrete components (e.g., each of the sides 202A, 202B, 202C, 202D is a discrete component, etc.). In some examples, the frame 200 is composed of one or more polymers (e.g., a thermoset plastic, a resin, an epoxy, etc.), one or more metals (e.g., copper, aluminum, steel, cast iron, etc.), one or more composites, one or more organic materials, and/or a combination thereof.

In the illustrated example of FIGS. 2A and 2B, the second side 202B of the frame 200 includes the first cable interface 211. In the illustrated example of FIGS. 2A and 2B, the first cable interface 211 is mounted on the first substrate 216. In other examples, the first cable interface 211 can be mounted on the body of the frame 200 (e.g., not on the first substrate 216, etc.). In the illustrated example of FIGS. 2A and 2B, the first cable interface 211 retains and guides an example first cable ribbon 222. In the illustrated example of FIGS. 2A and 2B, the first cable interface 211 is a cable clamp, which retains the first cable ribbon 222. In the illustrated example of FIGS. 2A and 2B, the first cable interface 211 is a discrete component coupled to the first substrate 216. In other examples, the first cable interface 211 is integral with the frame 200. In the illustrated example of FIGS. 2A and 2B, the first cable ribbon 222 extends from the top surface 210 of the package substrate 206. In the illustrated example of FIGS. 2A and 2B, the first cable ribbon 222 extends from the first recessed portion 208A of the package lid 112 to the first cable interface 211. In other examples, the first cable ribbon 222 can extend from the edge 209 of the package substrate 206.

In the illustrated examples of FIGS. 2A and 2B, the third side 202C of the frame 200 includes the second cable interface 212. In the illustrated example of FIGS. 2A and 2B, the second cable interface 212 is an edge connector. In the illustrated example of FIGS. 2A and 2B, the second cable interface 212 is integrally formed on the third side 202C (e.g., the second cable interface 212 is monolithic with the frame 200, etc.). In other examples, the second cable interface 212 can be a discrete component that is separately manufactured and coupled to the frame 200 (e.g., via one or more fasteners, via one or more chemical adhesives, via one or more interference fits, etc.).

In the illustrated example of FIGS. 2A and 2B, the second cable interface 212 is a socket that receives an example second cable ribbon 224, which extends from the edge 209 of the package substrate 206. In the illustrated example of FIGS. 2A and 2B, the second cable interface 212 includes an example opening 226. The opening 226 can receive a cable and couple (e.g., electrically couple, optically couple, etc.) the cable to the second cable ribbon 224. That is, the second cable interface 212 includes an internal interface (e.g., an electrical interface, an optical interface, etc.) that can couple an external cable to the second cable ribbon 224.

The first cable ribbon 222 and the second cable ribbon 224 can be coupled to another component associated with the compute unit assembly 100 of FIG. 1. For example, the first cable ribbon 222 can be coupled to a memory unit (e.g., volatile memory, non-volatile memory, etc.), a power supply, another integrated circuit package, an input/output device. In some examples, one or both of the cable ribbons 222, 224 are fiber optic cables (e.g., fiber optic ribbons, etc.). In some such examples, to prevent signal degradation and enable transmission of optical signals, the cable ribbons 222, 224 have stringent bending requirements (e.g., bending radii of less than ten times the diameter of the fibers of the ribbon can compromise optical signal transmission, etc.). In some such examples, the routing of the cable ribbons 222, 224 to the top surface 210 and the edge 209 and the relative lack of bending of the cable ribbons 222, 224 facilitates the transmission of light signals through the cable ribbons 222, 224. That is, the configuration of the cable interfaces 211, 212 facilitates the direct routing of fiber optic cables into the integrated circuit package 102 due to the lack of bending in the cable ribbons 222, 224. In some examples, one or both of the cable ribbons 222, 224 can be implemented by another type of cable (e.g., one or more insulated cables, a cable bundle, a braided cable, etc.).

The component interface 214 is disposed at the intersection of the third side 202C and the fourth side 202D. In other examples, the component interface 214 can be disposed at another location on the frame 200 (e.g., in the middle of one of the sides 202A, 202B, 202C, 202D, at a different intersection of the sides 202A, 202B, 202C, 202D, etc.). In the illustrated example of FIGS. 2A and 2B, the component interface 214 is integrally formed with the frame 200. In other examples, the component interface 214 can be manufactured separately and coupled to the frame 200.

In the illustrated example, the component interface 214 is a two-pin interface that is configured to receive a 2-pin header. In some examples, the component interface 214 can receive a cable connected to a fan (e.g., a high-speed fan, a fan coupled to the heat sink 110 of FIG. 1, etc.) and/or an output device (e.g., a light, etc.). In the illustrated example of FIGS. 2A and 2B, the component interface 214 is electrically coupled to the second substrate 218 via example first traces 228. The first traces 228 are electrical conduits that transmit signals between the component interface 214 (e.g., the component coupled to the component interface 214, etc.) to the second substrate 218. In other examples, the first traces 228 can be coupled to other circuitry (e.g., the first substrate 216, the integrated circuit package 102, etc.). In some examples, the first traces 228 can be coupled to the frame 200 via one or more interference fits (e.g., into a corresponding trench in the frame 200, etc.), via one or more chemical adhesives, via one or more fasteners, etc. Additionally or alternatively, the first traces 228 can be disposed internally within the body of the frame 200.

In the illustrated example of FIGS. 2A and 2B, the first substrate 216 is on the second side 202B of the frame 200. In the illustrated example of FIGS. 2A and 2B, the first substrate 216 supports an example die 230. In the illustrated example of FIGS. 2A and 2B, the die 230 are miniature dual in-line memory modules (mini-DIMM). In other examples, the die 230 can be implemented by any other suitable type of die and/or similar circuitry (e.g., a different type of memory module, an accelerator, a CPU, a GPU, etc.). Additionally or alternatively, dies and/or other circuitry can be mounted to the first substrate 216 (e.g., additional dies, passive circuitry features, etc.).

In the illustrated example of FIGS. 2A and 2B, the die 230 is coupled to the package substrate 206 by example second traces 231, which extend from the first substrate 216 to the package substrate 206. In some examples, the die 230 is electrically coupled to the second traces 231 via interconnects disposed in the first substrate 216. In some such examples, the traces 231 enable communication between the die 230 and the circuitry of the integrated circuit package 102. Additionally or alternatively, the second traces 231 can be disposed internally within the body of the frame 200.

In the illustrated example of FIGS. 2A and 2B, the second substrate 218 is on the fourth side 202D of the frame 200. In the illustrated example of FIGS. 2A and 2B, the second substrate 218 supports example passive circuit components 233 (also referred to herein as “passives.”). In some examples, the passive circuit components 233 are capacitors, inductors, resistors, and/or a combination thereof. Additionally or alternatively, the passive circuit components 233 can include one or more diodes, one or more transformers, one or transducers, etc. Additionally or alternatively, other components (e.g., active circuit components, dies, etc.) can be mounted on the second substrate 218.

In the illustrated example of FIGS. 2A and 2B, the second substrate 218 is electrically coupled to a third cable ribbon 232 and the first traces 228. In the illustrated example of FIGS. 2A and 2B, the third cable ribbon 232 extends between the integrated circuit package 102 and the second substrate 218. In the illustrated example of FIGS. 2A and 2B, the third cable ribbon 232 extends through the second recessed portion 208B of the package lid 112. In some examples, the third cable ribbon 232 is coupled to the top surface 210 of the package substrate 206. In other examples, the third cable ribbon 232 is coupled directly to the die(s) of the integrated circuit package 102 via one or more through silicon vias (TSVs).

In some examples, the second substrate 218 couples some or all of the passive circuit components 233 to the first traces 228 (e.g., coupled to the component interface 214, etc.) and/or to the third cable ribbon 232. In other examples, the first traces 228 and/or the third cable ribbon 232 is absent. In some such examples, the passive circuit components 233 and/or other components mounted on the second substrate 218 are only coupled to (1) the first traces 228, the component interface 214, and the component mounted thereto, or (2) the integrated circuit package 102.

In some examples, the first substrate 216 and/or the second substrate 218 can include heat spreader(s) and/or similar feature(s) that facilitate the conduction of heat from components mounted on the first substrate 216 (e.g., the die 230, the passive circuit components 233, etc.). In some examples, the positioning of the first substrate 216 enables a thermal interface to be formed with the cooler associated with the integrated circuit package 102, which facilitates the cooling of components mounted on the first substrate 216. For example, the frame 200 can include a heat spreader or similar feature that thermally couples the components mounted on one or both of the substrates 216, 218 to the heat sink 110 of FIG. 1.

The die 220 is coupled to the first side 202A of the frame 200. In the illustrated example of FIGS. 2A and 2B, the die 220 is enclosed in a package and directly mounted onto the frame 200 (e.g., not on a substrate coupled to the frame 200, etc.). In other examples, the die 220 is mounted on a substrate coupled to the frame 200 (e.g., a substrate similar to the substrates 216, 218, etc.). In the illustrated example of FIGS. 2A and 2B, the die 220 is coupled to an example antenna 234. In the illustrated example of FIGS. 2A and 2B, the antenna 234 extends from the die 220. In the illustrated example of FIGS. 2A and 2B, the antenna 234 extends along the first side 202A and the fourth side 202D. In other examples, the antenna 234 can extend in a different direction (e.g., away from the carrier 104 toward the heat sink 110 of FIG. 1, away from the carrier in a plane parallel to the plane of the package substrate 206, etc.).

The antenna 234 enables the die 220 to send and receive wireless communications. For example, the die 220 can be a Wi-Fi die. In other examples, the die 220 is implemented by another communication interface die (e.g., a Bluetooth communication interface, a cellular communication interface, etc.). In other examples, the die 220 can be implemented by any other suitable type of die (e.g., a memory unit, a processor, an accelerator, etc.). In some such examples, the antenna 234 is absent.

In the illustrated examples of FIGS. 2A and 2B, the alignment feature 221 is disposed on the third side 202C of the frame 200. In the illustrated examples of FIGS. 2A and 2B, the alignment feature 221 extends outboard from an exterior of the frame 200. The alignment feature 221 facilitates the alignment of the integrated circuit package 102 into the socket 109 of FIG. 1. In some examples, the alignment feature 221 is a boss (e.g., a pin, a spike, etc.) that is received by a corresponding opening on the bolster plate 108 of FIG. 1. In other examples, the alignment feature 221 is an opening that receives a corresponding boss extending from the alignment feature 221. The engagement of the alignment feature 221 and a corresponding alignment feature of the bolster plate 108 prevents the seating of the integrated circuit package 102 into the socket 109 in an improper orientation (e.g., rotated 180 degrees, etc.). In some examples, the presence of the alignment feature 221 on the carrier 104 (e.g., not on the bottom of the integrated circuit package 102, etc.) increases the surface area on the bottom of the integrated circuit package 102 available for connections to the printed circuit board 106, which reduces the required loading associated with the compute unit assembly 100 of FIG. 1.

Additionally or alternatively, the deposition of the alignment feature 221 on the frame 200 reduces the likelihood of the package substrate 206 contacting (e.g., bumping, colliding with, etc.) the sides of the socket 109 during the mounting of the integrated circuit package on the printed circuit board 106 of FIG. 1. In some such examples, the reduction of the likelihood of incidental contact with the package substrate 206 reduces the likelihood of damage to the package substrate 206 during the mounting of the integrated circuit package 102. As such, the alignment feature 221 facilitates the use of fragile materials in the package substrate 206 (e.g., glass cores, etc.).

In the illustrated example of FIG. 2B, the carrier 104 includes an example first twist tab 236A, an example second twist tab 236B, an example third twist tab 236C, and an example fourth twist tab 236D. In the illustrated example of FIG. 2B, the twist tabs 236A, 236B, 236C, 236D are seated in an example first slot 238A, an example second slot 238B, an example third slot 238C, and an example fourth slot 238D, respectively. In the illustrated example of FIG. 2B, the first twist tab 236A, the second twist tab 236B, the first slot 238A, and the second slot 238B are disposed on the second side 202B. In the illustrated example of FIG. 2B, the third twist tab 236C, the fourth twist tab 236D, the third slot 238C, and the fourth slot 238D are disposed on the fourth side 202D. In other examples, the twist tabs 236A, 236B, 236C, 236D and the slots 238A, 238B, 238C, 238D can be disposed at other suitable locations (e.g., two on the first side 202A and two on the third side 202C, one on each of the sides 202A, 202B, 202C, 202D, etc.).

The twist tabs 236A, 236B, 236C, 236D (also referred to herein as “retention clips” or “retention tabs”) are rotatably disposed in the slots 238A, 238B, 238C, 238D, respectively. In the illustrated example of FIG. 2B, the twist tabs 236A, 236B, 236C, 236D are positioned such that the twist tabs 236A, 236B, 236C, 236D extend over the package lid 112 of the integrated circuit package 102. In the illustrated example of FIG. 2B, the positioning of the twist tabs 236A, 236B, 236C, 236D prevents the integrated circuit package 102 from translating vertically upward from the carrier 104. To remove and/or install the integrated circuit package 102 from/into the carrier 104, the twist tabs 236A, 236B, 236C, 236D can be rotated within the slots 238A, 238B, 238C, 238D until (1) the first twist tab 236A and the second twist tab 236B are parallel to and aligned with the first slot 238A, the second slot 238B, and the second side 202B and (2) the third twist tab 236C and the fourth twist tab 236D are parallel to and aligned with the third slot 238C, the fourth slot 238D, and the fourth side 202D.

In the illustrated example of FIG. 2B, the twist tabs 236A, 236B, 236C, 236D include an example first screw interface 240A, an example second screw interface 240B, an example third screw interface 240C, and an example fourth screw interface 240D. The screw enables a user to rotate the twist tabs 236A, 236B, 236C, 236D between the position illustrated in FIGS. 2A and 2B (e.g., an installed position, etc.) and a position wherein the twist tabs 236A, 236B, 236C, 236D are disposed in the slots 238A, 238B, 238C, 238D (e.g., an uninstalled position, etc.). In other examples, the twist tabs 236A, 236B, 236C, 236D can be rotated in any other suitable manner. In some such examples, the twist tabs 236A, 236B, 236C, 236D do not include the screw interfaces 240A, 240B, 240C, 240D.

In the illustrated example of FIGS. 2A and 2B, the frame 200 includes the first cable interface 211, the second cable interface 212, the component interface 214, the first substrate 216, the second substrate 218, the die 220, and the alignment feature 221. In other examples implemented in accordance with the teachings disclosed herein, the frame 200 can include only the first cable interface 211, only the second cable interface 212, only the component interface 214, only the first substrate 216, only the second substrate 218, only the die 220, only the alignment feature 221 or some other combination of the first cable interface 211, the second cable interface 212, the component interface 214, the first substrate 216, the second substrate 218, the die 220, and/or the alignment feature 221. In other examples implemented in accordance with the teachings disclosed herein, some or all of the first cable interface 211, the second cable interface 212, the component interface 214, the first substrate 216, the second substrate 218, the die 220, and the alignment feature 221 can be disposed at other locations on the frame 200 than the location(s) illustrated in FIGS. 2A and 2B. In other examples implemented in accordance with the teachings disclosed herein, the frame 200 can include additional substrates and/or cable interfaces in addition to those depicted in FIGS. 2A and 2B.

FIG. 2C is a bottom view of the integrated circuit package 102 and the carrier 104. In the illustrated example of FIG. 2C, the carrier 104 includes the frames 200 of FIG. 2, which includes the sides 202A, 202B, 202C, 202D of FIG. 2. In the illustrated example of FIG. 2C, the frame 200 includes an example first retention tab 242A, an example second retention tab 242B, an example third retention tab 242C, and an example fourth retention tab 242D. In the illustrated example of FIG. 2C, the retention tabs 242A, 242B, 242C, 242D extend from the first side 202A, the second side 202B, the third side 202C, and the fourth side 202D, respectively, into the opening 204. In other examples, the retention tabs 242A, 242B, 242C, 242D can be disposed at other suitable locations on the frame 200 (e.g., two on the first side 202A and two on the third side 202C, one on each of the sides 202A, 202B, 202C, 202D, etc.). In some examples, the retention tabs 242A, 242B, 242C, 242D can include one or more contact pads and/or other interfaces that enable an electrical coupling with the integrated circuit package 102. An example interface between a retention tab and a package substrate is described below in conjunction with FIG. 3.

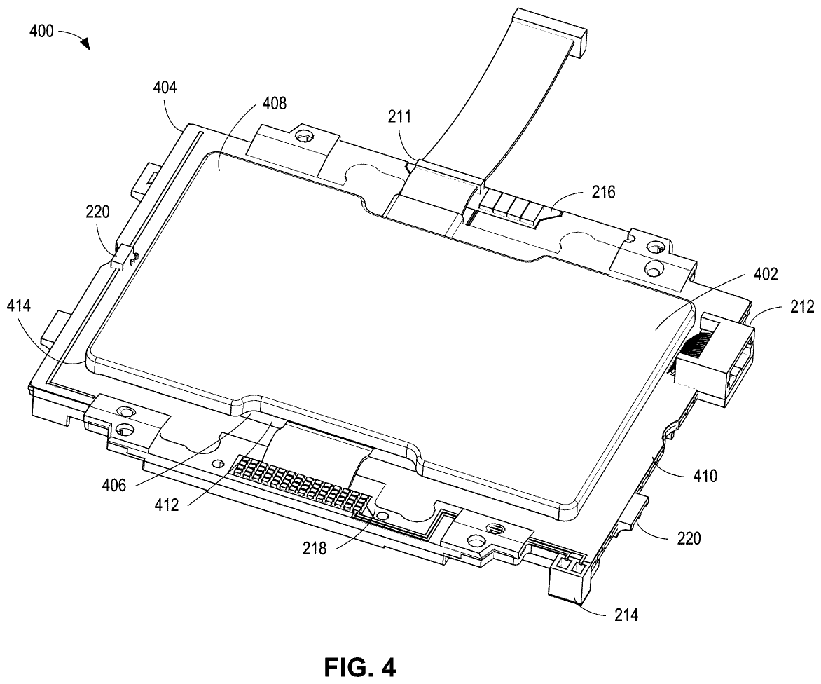

In the illustrated example of FIG. 2C, an example bottom surface 244 of the package substrate 206 of the integrated circuit package 102 abuts the retention tabs 242A, 242B, 242C, 242D. The positioning of the retention tabs 242A, 242B, 242C, 242D prevents the integrated circuit package 102 from translating vertically downward from the carrier 104. The abutment of the integrated circuit package 102 on the retention tabs 242A, 242B, 242C, 242D and the twist tabs 236A, 236B, 236C, 236D of FIG. 2B retains the integrated circuit package 102 within the carrier 104. The bottom surface 244 of the package substrate 206 can form an interface with a socket of a printed circuit package (e.g., the socket 109 of the printed circuit package 102, etc.). In some examples, some or all of the retention tabs 242A, 242B, 242C, 242D, and/or the twist tabs 236A, 236B, 236C, 236D of FIG. 2B are absent. In some such examples, the carrier 104 can be coupled to the integrated circuit package 102 in another suitable manner. An example assembly including an integrated circuit package that is rigidly coupled to a carrier implemented in accordance with teachings of this disclosure is described below in conjunction with FIG. 4.

FIG. 3A is a detailed view of the second traces 231 identified in the circle 246 of FIG. 2A. In FIG. 3A, the integrated circuit package 102 is omitted so that the printed circuit board 106 is visible through the opening 204 in the carrier 104. In the illustrated example of FIG. 3A, the traces 228 are coupled to the package substrate 206 via an example first plurality of pads 302 disposed on the printed circuit board 106. FIG. 3B is a schematic top view of the second retention tab 242B of FIG. 2C. In the illustrated example of FIG. 3B, the second retention tab 242B includes an example second plurality of pads 304 disposed on an example tab top surface 306. In the illustrated example of FIG. 3A, the second traces 231 extend over an example frame top surface 308 of the frame 200 and an example interior surface 310 of the frame 200. In some examples, the second traces 231 are electrically coupled to the second plurality of pads 304. In some such examples, the first plurality of pads 302 are electrically coupled to the second plurality of pads 304. In some such examples, the routing of the traces 231 through the second retention tab 242B between the components mounted on the carrier 104 (e.g., the die 230, etc.) and the integrated circuit package 102 enables electrical communication through the bottom surface 244 of FIG. 2C and reduces the density of the connections between the integrated circuit package 102 and the socket 109.

FIG. 4 is a perspective view of another example integrated circuit package assembly 400 implemented in accordance with teachings of this disclosure. In the illustrated example of FIG. 4, the integrated circuit package assembly 400 includes an example integrated circuit package 402 and an example carrier 404. The integrated circuit package assembly 400 can implement the carrier 104 and the integrated circuit package 102 of the assembly 100 of FIG. 1. The integrated circuit package 402 and the example carrier 404 are similar to the integrated circuit package 102 and the carrier 104 of FIGS. 1-2C, respectively, except as noted otherwise. In the illustrated example of FIG. 4, the integrated circuit package 402 includes an example package substrate 406 and an example package lid 408. In the illustrated example of FIG. 4, the carrier 404 includes an example frame 410.

In the illustrated example of FIG. 4, the frame 410 includes the first cable interface 211 of FIGS. 2A and 2B, the second cable interface 212 of FIGS. 2A and 2B, the component interface 214 of FIGS. 2A and 2B, the first substrate 216 of FIGS. 2A and 2B, the second substrate 218 of FIGS. 2A and 2B, the die 220 of FIGS. 2A and 2B, and the alignment feature 221 of FIGS. 2A and 2B. In other examples implemented in accordance with teachings disclosed herein, the frame 410 can include only the first cable interface 211, only the second cable interface 212, only the component interface 214, only the first substrate 216, only the second substrate 218, only the die 220, only the alignment feature 221 or some other combination of the first cable interface 211, the second cable interface 212, the component interface 214, the first substrate 216, the second substrate 218, the die 220, and the alignment feature 221. In other examples implemented in accordance with the teachings disclosed herein, some or all of the first cable interface 211, the second cable interface 212, the component interface 214, the first substrate 216, the second substrate 218, the die 220, and the alignment feature 221 can be disposed at other locations on the frame 200 than the location(s) illustrated in FIG. 4. In other examples implemented in accordance with the teachings disclosed herein, the frame 200 can include additional substrates and/or cable interfaces in addition to those depicted in FIG. 4.

In the illustrated example of FIG. 4, the frame 410 is directly coupled to the package substrate 206. For example, the frame 410 can be coupled to an example top surface 412 of the package substrate 206 via a chemical adhesive (e.g., glue, etc.). Additionally or alternatively, the frame 410 can be coupled to an example edge 414 of the package substrate 206 and/or the lid 408. Additionally or alternatively, the frame 410 can be soldered to the package substrate 406. In some such examples, the traces associated with the carrier 404 (e.g., traces extending from features mounted on the substrates 216, 218 to the integrated, etc.) can be routed through the frame 410 into the top surface 412 and/or the edge 414 of the package substrate 406.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, integrated circuit package carriers with integrated substrates and cable interfaces are disclosed herein. Examples disclosed herein improve the performance of an integrated circuit package by enabling more packaging of components on a PCB components near the integrated circuit package, which reduces the overall size of PCB assemblies. Examples disclosed herein simplify trace routing through the printed circuit board by providing alternative routing into the top surface and/or edge of the integrated circuit package. Examples disclosed herein reduce the density of LGA connections between the integrated circuit package and printed circuit board, which reduces loading on the assembly and the bending and signal degradation associated therewith.

Integrated circuit packages including carriers with incorporated substrates and interfaces are disclosed herein. Further examples and combinations thereof include the following:

Example 1 includes an integrated circuit package carrier comprising a frame including an opening to receive an integrated circuit package, and at least one of (a) a circuitry component on a substrate on a surface of the frame or (a) a cable interface directly coupled to the frame.

Example 2 includes the integrated circuit package carrier of any preceding example, wherein the integrated circuit package carrier includes the circuitry component on the substrate, the circuitry component includes a communication interface die and the integrated circuit package carrier further includes an antenna extending along a side of the frame.

Example 3 includes the integrated circuit package carrier of any preceding example, wherein the integrated circuit package carrier includes the cable interface and the cable interface includes a cable clamp.

Example 4 includes the integrated circuit package carrier of any preceding example, wherein the integrated circuit package carrier includes the cable interface and the cable interface is an edge connector.

Example 5 includes the integrated circuit package carrier of any preceding example, wherein the edge connector is integral with the frame.

Example 6 includes the integrated circuit package carrier of any preceding example, wherein the integrated circuit package carrier includes the circuitry component on the substrate and further including a cable ribbon extending from the substrate to an interior of the frame.

Example 7 includes the integrated circuit package carrier of any preceding example, further including an alignment feature extending from an exterior of the frame.

Example 8 includes an apparatus including an integrated circuit package to be coupled to a socket, a heat sink thermally coupled to the integrated circuit package, and a carrier clip adjacent to the heat sink, the carrier clip including a frame receiving the integrated circuit package, and at least one of (a) a circuitry component on a substrate coupled to a surface of the frame or (b) a cable interface.

Example 9 includes the apparatus of any preceding example, wherein the integrated circuit package is rigidly coupled to the carrier clip via a chemical adhesive.

Example 10 includes the apparatus of any preceding example, wherein the carrier clip includes the cable interface and further including a cable extending through the cable interface and coupled to the integrated circuit package.

Example 11 includes the apparatus of any preceding example, wherein the cable is a fiber optic cable.

Example 12 includes the apparatus of any preceding example, wherein the carrier clip includes the circuitry component on the substrate and the carrier clip includes a trace electrically coupling the circuitry component and the integrated circuit package.

Example 13 includes the apparatus of any preceding example, wherein the carrier clip includes the circuitry component and the circuitry component is a passive circuit component carried by the substrate.

Example 14 includes the apparatus of any preceding example, wherein the carrier clip includes the circuitry component and the circuit component is thermally coupled to the heat sink.

Example 15 includes an electronic device including a printed circuit board including a socket, an integrated circuit package to be coupled to the socket, a heat sink thermally coupled to the integrated circuit package, and a carrier adjacent to the heat sink, the carrier including a frame including an opening, the integrated circuit package disposed in the opening, and at least one of (1) a circuitry component on a substrate coupled to a surface of the frame or (2) a cable interface.

Example 16 includes the electronic device of any preceding example, wherein the carrier includes a slot, and a tab rotatably disposed in the slot, the tab retaining the integrated circuit package in the frame.

Example 17 includes the electronic device of any preceding example, wherein the frame is rigidly coupled to the integrated circuit package.

Example 18 includes the electronic device of any preceding example, wherein the carrier includes the circuitry component on the substrate and further including a cable extending from the substrate to the integrated circuit package.

Example 19 includes the electronic device of any preceding example, wherein the carrier includes a tab abutting a side of the integrated circuit package, the side received by the socket.

Example 20 includes the electronic device of any preceding example, wherein the carrier includes the substrate, a contact pad on the tab, and a trace extending between the substrate and the contact pad.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit package carrier comprising:
a frame including an opening to receive an integrated circuit package; and
at least one of (a) a circuitry component on a substrate on a surface of the frame or (a) a cable interface directly coupled to the frame.

2. The integrated circuit package carrier of claim 1, wherein the integrated circuit package carrier includes the circuitry component on the substrate, the circuitry component includes a communication interface die and the integrated circuit package carrier further includes an antenna extending along a side of the frame.

3. The integrated circuit package carrier of claim 1, wherein the integrated circuit package carrier includes the cable interface and the cable interface includes a cable clamp.

4. The integrated circuit package carrier of claim 1, wherein the integrated circuit package carrier includes the cable interface and the cable interface is an edge connector.

5. The integrated circuit package carrier of claim 4, wherein the edge connector is integral with the frame.

6. The integrated circuit package carrier of claim 1, wherein the integrated circuit package carrier includes the circuitry component on the substrate and further including a cable ribbon extending from the substrate to an interior of the frame.

7. The integrated circuit package carrier of claim 1, further including an alignment feature extending from an exterior of the frame.

8. An apparatus including:
an integrated circuit package to be coupled to a socket;
a heat sink thermally coupled to the integrated circuit package; and
a carrier clip adjacent to the heat sink, the carrier clip including:
a frame receiving the integrated circuit package; and
at least one of (a) a circuitry component on a substrate coupled to a surface of the frame or (b) a cable interface.

9. The apparatus of claim 8, wherein the integrated circuit package is rigidly coupled to the carrier clip via a chemical adhesive.

10. The apparatus of claim 8, wherein the carrier clip includes the cable interface and further including a cable extending through the cable interface and coupled to the integrated circuit package.

11. The apparatus of claim 10, wherein the cable is a fiber optic cable.

12. The apparatus of claim 8, wherein the carrier clip includes the circuitry component on the substrate and the carrier clip includes a trace electrically coupling the circuitry component and the integrated circuit package.

13. The apparatus of claim 8, wherein the carrier clip includes the circuitry component and the circuitry component is a passive circuit component carried by the substrate.

14. The apparatus of claim 8, wherein the carrier clip includes the circuitry component and the circuit component is thermally coupled to the heat sink.

15. An electronic device including:
a printed circuit board including a socket;
an integrated circuit package to be coupled to the socket;
a heat sink thermally coupled to the integrated circuit package; and
a carrier adjacent to the heat sink, the carrier including:
a frame including an opening, the integrated circuit package disposed in the opening; and
at least one of (1) a circuitry component on a substrate coupled to a surface of the frame or (2) a cable interface.

16. The electronic device of claim 15, wherein the carrier includes:
a slot; and
a tab rotatably disposed in the slot, the tab retaining the integrated circuit package in the frame.

17. The electronic device of claim 15, wherein the frame is rigidly coupled to the integrated circuit package.

18. The electronic device of claim 15, wherein the carrier includes the circuitry component on the substrate and further including a cable extending from the substrate to the integrated circuit package.

19. The electronic device of claim 15, wherein the carrier includes a tab abutting a side of the integrated circuit package, the side received by the socket.

20. The electronic device of claim 19, wherein the carrier includes:
the substrate;
a contact pad on the tab; and
a trace extending between the substrate and the contact pad.
